(19) United States
(12) Patent Application Publication
(10) Pub. No.: US 2004/0175845 A1
(43) Pub. Date: Sep. 9, 2004

(54) Method of forming a flux concentrating layer of a magnetic device

(76) Inventors: Jaynal A. Molla, Gilbert, AZ (US); John J. D'Urso, Chandler, AZ (US); J. Jack Ren, Phoenix, AZ (US)

Correspondence Address: FREESCALE SEMICONDUCTOR, INC., LAW DEPARTMENT, 7700 WEST PARMER LANE MD:TX32/PL02, AUSTIN, TX, 78729, US

(21) Appl. No.: 10/377,952

(22) Filed: Mar. 3, 2003

(51) Int. Cl. H01L 21/00

(52) U.S. Cl. 438/3

(57) ABSTRACT

A method of forming a magnetic device, especially the digit line of a magnetic random access memory (MRAM) device is disclosed. The digit line includes a stack of materials that includes a barrier layer, a seed layer and a soft magnetic layer that is electrochemically deposited. Preferably, the barrier layer and the seed layer are formed by physical vapor deposition (PVD) and the soft magnetic layer is formed by electroless plating. In one embodiment, the barrier layer includes tantalum, the seed layer includes ruthenium and the soft magnetic layer includes nickel and iron.

### FIELD OF THE INVENTION

This invention relates generally to semiconductor devices, and more specifically, to magnetic devices, such as magnetic random access memory (MRAM) devices.

### BACKGROUND

Memory cells in MRAM devices are programmed by a magnetic field created from a current carrying conductor. Typically two orthogonal conductors, one formed underneath a magnetic memory bit, hereinafter referred to as a digit line, and one formed on top of a magnetic memory bit, hereinafter referred to as a bit line, are arranged in a cross point matrix to provide magnetic fields for bit programming.

The digit line includes a conductive material surrounded by a flux concentrating layer (magnetic cladding member). The flux concentrating layer is formed using a high-permeability material that has magnet domains in the plane of a cross-section of the digit or bit lines. The magnet domains are magnetized and demagnetized upon the application and removal of an applied magnetic field. When current is applied through the conductive material, the corresponding magnetic fields associated with the flux concentrating layer help to enhance the magnitude and more effectively focus the overall magnetic field associated with the digit line towards its associated memory element.

Typically, a soft magnetic material is used for the flux concentrating layer. Traditionally, physical vapor deposition (PVD) techniques are used to deposit the soft magnetic material. PVD techniques, however, do not form conformal films, especially if being formed within narrow trenches. Since PVD is a unidirectional process the film is formed on the horizontal portions of the trenches and the coverage of the film on the sidewall, which are substantially vertical, is poor. To achieve the desired shielding requirements, the soft magnetic material should cover the sidewall and bottom of trenches on the order of at least 10 nanometers, which PVD does not achieve. Increasing aspect ratios (depth to width) further limits the prospect of good coverage inside the features using such a process. Thus, a need exists for a different process that can meet the conformal and thickness requirements for the flux concentrating layers of the digit line of MRAM devices.

### BRIEF DESCRIPTION OF THE DRAWINGS

The present invention is illustrated by way of example and is not limited by the accompanying figures, in which like references indicate similar elements.

FIGS. 1-6 illustrate in cross-section the formation of a digit line of a magnetic random access memory (MRAM) device in accordance with an embodiment of the present invention.

Skilled artisans appreciate that elements in the figures are illustrated for simplicity and clarity and have not necessarily been drawn to scale. For example, the dimensions of some of the elements in the figures may be exaggerated relative to other elements to help improve the understanding of the embodiments of the present invention.

### DETAILED DESCRIPTION OF THE DRAWINGS

An electrochemical deposition (ECD) process is used to deposit magnetic cladding material to form the flux concentrating layers of a digit line in an MRAM device. In one embodiment, the ECD is an electroless plating process that provides a conformal and uniform film deposition of the flux concentrating layer. The process meets the required thickness and conformity demands of the flux concentrating layers of the MRAM device. A more detailed description of one embodiment of the ECD process is described with respect to the figures.

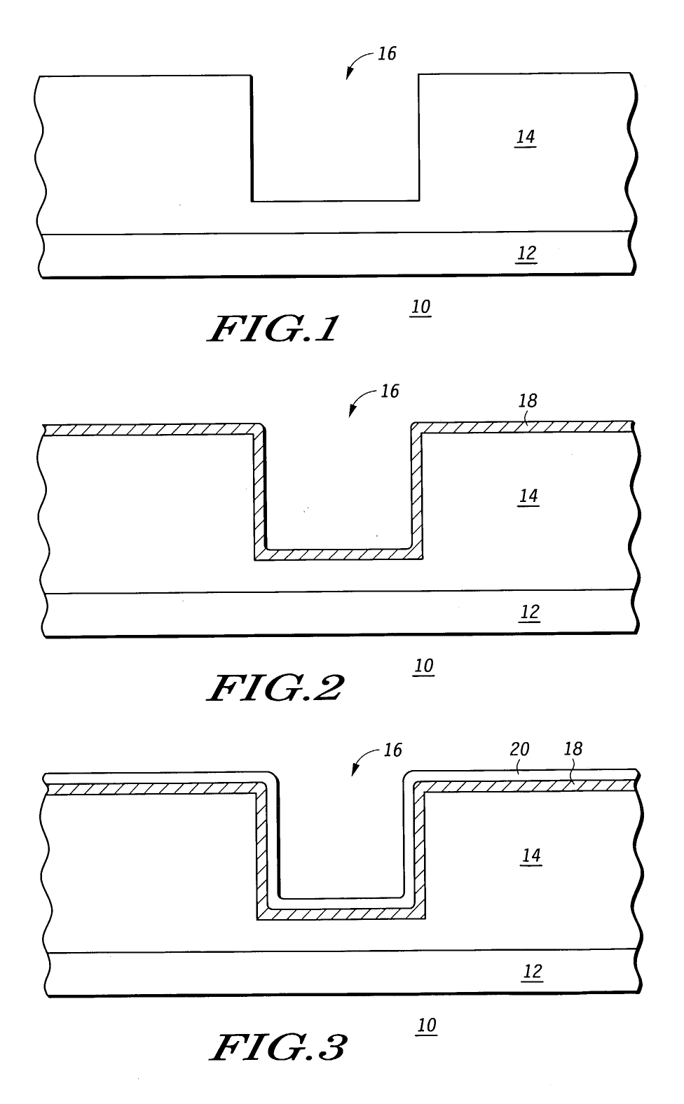

FIG. 1 illustrates in a cross-sectional view a substrate 12 on which a magnetic random access memory (MRAM) device 10 is formed. Although not shown, semiconductor devices and other layers may be formed within or over the substrate 12. For example, logic transistors may be formed in the substrate 12 using conventional methods. The substrate 12 is a semiconductor substrate, which is preferably silicon, silicon germanium, gallium arsenide, silicon-on-insulator, the like, and combinations of the above. A first dielectric layer 14 is formed over the substrate 12 by chemical vapor deposition (CVD), physical vapor deposition (PVD), thermal growth, the like or combinations of the above. The first dielectric layer 14 is preferably silicon dioxide formed using tetraethylorthosilane (TEOS), but can be any other dielectric material, such as a low dielectric constant material (i.e., a dielectric material with a dielectric constant less than that of silicon dioxide). The first dielectric layer 14 is etched using a conventional fluorocarbon chemistry and a photoresist mask (not shown) to form an opening 16. After forming the opening 16, the photoresist mask is removed using an oxygen ash process. The fabrication of a digit line within the opening 16 will be discussed in regards to FIGS. 2-6.

After forming the opening 16, a first barrier layer 18 is formed over the substrate 12 by CVD, PVD, atomic layer deposition (ALD), the like or combinations of the above. In other words, the first barrier layer 18 is deposited along the walls of the opening 16 and over the exposed top surface of the first dielectric layer 14. In one embodiment, the first barrier layer 18 is formed of a refractory metal, such as tantalum (Ta), tantalum nitride (TaN), tantalum silicon nitride (TaSiN), or the like. The first barrier layer 18 stops diffusion of atoms between a subsequently formed flux concentrating layer and the first dielectric layer 14 and also serves as a glue layer between the two layers.

As shown in FIG. 3, a first seed layer 20 is formed over the first barrier layer 18 by PVD, CVD, ALD, the like, or combinations of the above to enable the flux concentrating layer (which is subsequently formed) to be electrolessly plated within the opening 16 since the flux concentrating layer cannot be electrolessly deposited directly on the first barrier layer 18. The first seed layer 20 can be any material, such as ruthenium (Ru), palladium (Pd), copper (Cu), the like and combinations of the above and is preferably a thin layer of less than approximately 100 Angstroms.

After forming the first seed layer 20, the MRAM device 10 is immersed in an electroless plating bath to electrolessly plate a first flux concentrating layer 22. The resulting structure is shown in FIG. 4. The first flux concentrating layer 22 is a highly permeable and magnetically soft (i.e., low coercitivity) electrically conductive magnetic material. Magnetostriction of the layer is low. Nickel iron (NiFe)-containing alloys, such as NiFeP and NiFeB, work well for this flux concentrating layer. The first flux concentrating layer 22 focuses the magnetic flux produced by the current flowing in the conductor, therefore reducing the amount of current required to produce the desired action.

To form a NiFeB flux concentrating layer, the electroless plating bath may include a nickel source, such as nickel chloride or nickel sulfate, an iron source, such as iron chloride or iron sulfate, complexing agents, which are preferably tartrate and glycine, and a reducing agent. In electrolytic plating an outside power supply is used to pass current through the bath to the wafer for deposition to occur. In contrast, electroless plating does not use an outside power supply. Instead, the reducing agent is used to provide electrons. In a preferred embodiment, the reducing agent is dimethylamineborane (DMAB), which is the boron source. Thus, the presence of boron in the flux concentrating layer is due to the reducing agent being used. It is not necessary for the functionality of the MRAM device that the flux concentrating layer include boron. Electroless deposition (i.e., electroless plating) of the first flux concentrating layer 22 is performed at much lower temperatures than PVD. Preferably, the bath temperature is between 40-60 degrees Celsius, whereas PVD is typically performed at temperatures approximately equal to or greater than 200 degrees Celsius. The deposition is conformal in the opening 16 because such a process is a three-dimensional growth process. In other words, the first flux concentrating layer 22 grows in all directions at an equal rate, resulting in a conformal coating on the first seed layer 20.

The thickness of the deposited film is controlled by the immersion time of the MRAM device 10 in the electroless plating bath. Preferably, a thickness of approximately 150-250 Angstroms is desirable for the first flux concentrating layer 22. To achieve such a thickness, the MRAM device 10 should be immersed for approximately 1-2 minutes. The first seed layer 20 acts as an activation layer by initiating the electroless plating reaction.

As shown in FIG. 5, formed over the first flux concentrating layer 22 is a second barrier layer 24 that acts as a diffusion barrier between the first flux concentrating layer 22 and the digit line's bulk conductive material, which is subsequently formed. Preferably the first flux concentrating layer 22 is a nickel iron-containing alloy and the bulk conductive material includes copper (Cu). Nickel iron alloys and copper intermix readily, creating a magnetic dead layer in the first flux concentrating layer 22. This dead layer reduces the effective thickness of the high permeability material of the first flux concentrating layer 22 thereby reducing its effectiveness. Thus, the second barrier layer 24 is used to prevent the dead layer from forming. The second barrier layer 24 is conductive and preferably does not have a higher selectivity to the polishing chemistries used to remove the subsequently formed bulk conductive material and the first flux concentrating layer 22 than the materials that are being removed in each process. If the bulk conductive material is copper and the flux concentrating layer is a nickel iron-containing alloy, it is preferable to use a tantalum-containing material, such as tantalum (Ta) or tantalum nitride (TaN), for the second barrier layer 24.

A second seed layer 25, which is conductive, is optionally formed over the second barrier layer 24 by PVD, CVD, ALD, the like and combinations of the above. The second seed layer 25 is formed if an overlying conductive material 26 is formed on the MRAM device 10 by plating. Preferably, the second seed layer 25 and the conductive material 26 are copper (Cu) containing. The conductive material 26 can be formed by electroplating to fill the opening 16. However, any other process can be used.

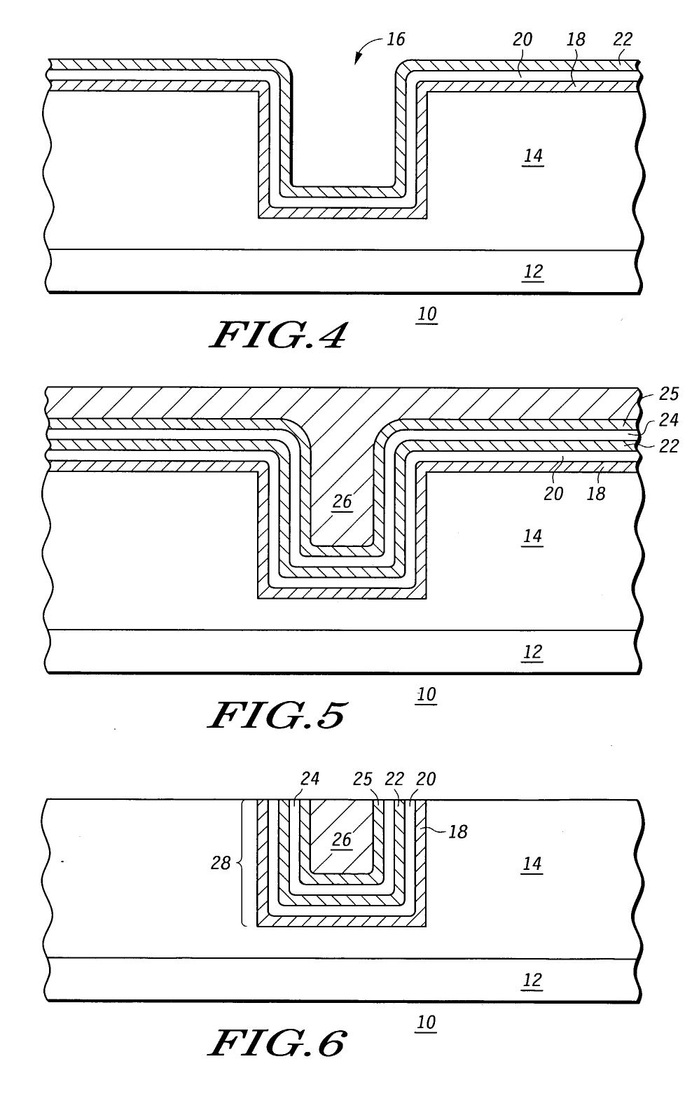

As illustrated in FIG. 6, the MRAM device 10 is planarized by an etch back or a chemical mechanical polishing (CMP) process to remove portions of the first barrier layer 18, the first seed layer 20, the first flux concentrating layer 22, the second barrier layer 24, the optional second seed layer 25 and the conductive material 26 that are not within the opening 16 (i.e., the portions of such layers that are over the first dielectric layer 14) to form a digit line 28. As previously discussed, the digit line 28 is a conductor that is formed underneath a magnetic memory bit of the MRAM device to provide a magnetic field for bit programming.

After forming the digit line 28, processing continues to form other portions of the MRAM device, such as a MRAM bit and a MRAM bit line. Conventional processing known to a skilled artisan can be used and thus is not explained herein.

By now it should be appreciated that there has been provided a process for forming flux concentrating layers in a digit line of an MRAM device. The electroless plating process provides for a conformal flux concentrating layer within openings. Having a uniform thickness provides for better field boost and tight switching distribution. In addition, superior cladding properties including low coercitivity and remanacence are also achieved. Furthermore, the common “bread-loaf” effect that often occurs at the top of openings when depositing a material in an opening is prevented. Since the electrochemical deposition occurs atom by atom, the process is extendable to small features. In addition, the process can be formed using a conventional tool, which is relatively inexpensive. Furthermore, as previously described the electroless plating process is a low temperature process, unlike PVD, which is desirable for MRAM processing.

In the foregoing specification, the invention has been described with reference to specific embodiments. However, one of ordinary skill in the art appreciates that various modifications and changes can be made without departing from the scope of the present invention as set forth in the claims below. Furthermore, although an MRAM device was described, this process is suitable for GMR (giant magnetoresistive) MRAM devices as well. Although the flux concentrating layers were described above as being nickel iron containing materials, they may be any other suitable material. For example they may be cobalt containing (CoFeB, CoFe, the like, or combinations of the above). In the embodiments where the flux concentrating layers include cobalt an overlying barrier layer such as the second barrier layer 24 in FIGS. 5-6 is not needed since cobalt containing materials include both magnetic and barrier properties. Accordingly, the specification and figures are to be regarded in an illustrative rather than a restrictive sense, and all such modifications are intended to be included within the scope of the present invention.

Moreover, the terms front, back, top, bottom, over, under and the like in the description and in the claims, if any, are used for descriptive purposes and not necessarily for describing permanent relative positions. It is understood that the terms so used are interchangeable under appropriate circumstances such that the embodiments of the invention described herein are, for example, capable of operation in other orientations than those illustrated or otherwise described herein.

Benefits, other advantages, and solutions to problems have been described above with regard to specific embodiments. However, the benefits, advantages, solutions to problems, and any element(s) that may cause any benefit, advantage, or solution to occur or become more pronounced are not to be construed as a critical, required, or essential feature or element of any or all the claims. As used herein, the terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus. The terms “a” or “an”, as used herein, are defined as one or more than one. The term “plurality”, as used herein, is defined as two or more than two. The term “another”, as used herein, is defined as at least a second or more.

What is claimed is:

1. A method of forming a magnetic device, the method comprising:
providing a substrate;
forming a dielectric layer over the substrate;
forming a trench within the dielectric layer;
forming a first barrier layer within the trench;
forming a first seed layer over the first barrier layer;
electrochemically depositing a soft magnetic material over the first seed layer;
forming a second barrier layer over the soft magnetic material; and
forming a metal layer over the second barrier layer.

2. The method of claim 1, wherein electrochemically depositing the soft magnetic material further comprises electrolessly plating the soft magnetic material.

3. The method of claim 1, wherein forming the first barrier layer, the first seed layer, and the second barrier layer are performed by a method selected from the group consisting of physical vapor deposition (PVD), chemical vapor deposition (CVD) and atomic layer deposition (ALD).

4. The method of claim 1, wherein forming the metal layer comprises:
depositing a second seed layer over the second barrier layer; and
electroplating the metal layer over the second seed layer.

5. The method of claim 4, wherein forming the metal layer comprises forming a layer comprising copper.

6. The method of claim 1, further comprising:
planarizing the substrate to remove portions of the first barrier layer, the first seed layer, the soft magnetic material, the second barrier layer and the metal layer that are outside the trench.

7. The method of claim 1, wherein forming the first barrier layer comprises depositing the same material as the second barrier layer.

8. The method of claim 1, wherein:
forming the first barrier layer comprises depositing a material comprising tantalum;
forming the first seed layer comprises depositing a material comprising an element selected from the group consisting of ruthenium and palladium; and
forming the second barrier layer comprises depositing a material comprising tantalum.

9. The method of claim 1, wherein depositing the soft magnetic material comprises depositing a material comprising an element selected from the group consisting of cobalt, nickel and iron.

10. The method of claim 1, wherein forming the first barrier layer, forming the first seed layer, electrochemically depositing the soft magnetic material, forming the second barrier layer and forming a metal layer are processes used in forming a digit line of a magnetic device.

11. A method of forming a magnetic device, the method comprising:
providing a substrate;
forming a dielectric layer over the substrate;
forming a trench within the dielectric layer;
depositing a first barrier layer within the trench;
depositing a first seed layer over the first barrier layer;
electrolessly plating a soft magnetic material over the first seed layer;
depositing a second barrier layer over the soft magnetic material; and
forming a metal layer over the second barrier layer.

12. The method of claim 11, wherein depositing the first barrier layer, the first seed layer, and the second barrier layer are performed by PVD.

13. The method of claim 11, wherein forming the metal layer comprises:
depositing a second seed layer over the second barrier layer; and
electroplating the metal layer over the second seed layer.

14. The method of claim 13, wherein forming the metal layer comprises forming a layer comprising copper.

15. The method of claim 11, further comprising:
removing portions of the first barrier layer, the first seed layer, the soft magnetic material, the second barrier layer and the metal layer that are outside the trench.

16. The method of claim 11, wherein:
forming the first barrier layer comprises depositing a material comprising tantalum;
forming the first seed layer comprises depositing a material comprising an element selected from the group consisting of ruthenium and palladium; and
forming the second barrier layer comprises depositing a material comprising tantalum.

17. The method of claim 16, wherein depositing the soft magnetic material comprises depositing a material comprising an element selected from the group consisting of cobalt, nickel, and iron.

18. The method of claim 17, wherein forming the first barrier layer comprises depositing the same material as the second barrier layer.

19. The method of claim 11, wherein depositing a first barrier layer, depositing the first seed layer, electrolessly plating the soft magnetic material, depositing the second barrier layer and forming the metal layer are processes used in forming a digit line in a magnetic device.

20. A method of forming a magnetic device, the method comprising:
providing a semiconductor substrate;
forming a dielectric layer over the semiconductor substrate;
forming a trench within the dielectric layer;
depositing a first barrier layer comprising tantalum within the trench, wherein the depositing is performed using physical vapor deposition (PVD);
depositing a first seed layer comprising ruthenium over the first barrier layer, wherein the depositing is performed using PVD;
electrolessly plating a soft magnetic material comprising iron and nickel over the first seed layer;
depositing a second barrier layer comprising tantalum over the soft magnetic material, wherein the depositing is performed using PVD;
depositing a second seed layer comprising copper over the second barrier layer;
plating a metal layer comprising copper over the second seed layer; and
removing portions of the first barrier layer, the first seed layer, the soft magnetic material, the second barrier layer and the metal layer that are outside the trench.
